(19) United States
(12) Patent Application Publication
(10) Pub. No.: US 2025/0343169 A1
(43) Pub. Date: Nov. 6, 2025

(54) ENCAPSULATING A PORTION OF A THROUGH-SILICON-VIA

(71) Applicant: International Business Machines Corporation, Armonk, NY (US)

(72) Inventors: Mukta Ghate Farooq, HOPEWELL JCT, NY (US); James J. Kelly, Schenectady, NY (US)

(21) Appl. No.: 18/655,509

(22) Filed: May 6, 2024

(51) Int. Cl. H01L 23/00; H01L 21/768; H01L 23/48; H01L 23/522

(52) U.S. Cl. CPC H01L 23/564; H01L 21/76804; H01L 21/76832; H01L 21/7684; H01L 21/76843; H01L 21/76877; H01L 21/76898; H01L 23/481; H01L 23/5226

(57) ABSTRACT

A semiconductor structure that with a via last through-silicon-via hole that has a dielectric liner surrounds a sidewall of the top portion of the through-silicon-via hole that is above and contacting the top surface of the semiconductor substrate. A through-silicon-via encapsulation is directly on and surrounds the dielectric liner around the top portion of the through-silicon-via hole. The through-silicon-via encapsulant can be composed of a refractory metal that is electrically isolated from the completed through-silicon-via by at least the dielectric liner.

### BACKGROUND

The disclosure generally relates to forming semiconductor devices, and more specifically, to a method of forming through-silicon-vias and the resulting structures.

Through-silicon vias (TSVs) are electrical interconnects that are etched into a silicon wafer. TSVs can also be referred to as through-wafer vias. The primary benefit that comes from the use of TSVs is reduced interconnect length with short vertical connections through thinned silicon die. The TSV's enable reduced latency, lower capacitance, lower inductance, and permit higher speed communications, higher numbers of interconnections, and lower power level communication links between circuits. The use of thinned wafers with TSVs and stacked semiconductor chips with TSVs permit the miniaturization of integrated multi-chip systems. Several types of TSVs have been created to address different design and performance requirements. Several methods of forming TSVs have evolved including via first, via middle, or via last. In via first TSVs, the TSVs are created in the semiconductor wafer before the active circuitry is fabricated on the silicon wafer. In via first TSVs, the TSVs are connected to the integrated circuits' active layers. In via middle TSVs, the TSVs are created after the active circuitry is fabricated using front-end-of-line semiconductor processes but before the back-end-of-line fabrication of interconnect metallization layers above the active circuits. The middle via approach is primarily used to connect both the active and passive layers of the integrated circuits through TSVs. In via last TSVs, the TSVs are fabricated after the fabrication of active layers and after the front side interconnect wiring layers are formed using back-end-of-line semiconductor processes. The via last TSV approach provides TSVs that can connect to the next level of packaging such as an external package or another semiconductor substrate when stacking semiconductor chips.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure with a top portion of a through-silicon-via hole on a semiconductor substrate that has a dielectric liner surrounding a sidewall of the top portion of the through-silicon-via hole and a through-silicon-via encapsulation surrounding the dielectric liner.

Aspects of the disclosed invention relate to a semiconductor structure that includes a top portion of a through-silicon-via (TSV) above the top surface of a semiconductor substrate. A dielectric liner contacts a sidewall of the top portion of the TSV, where the dielectric liner resides on at least a top surface of a plurality of front side interconnect wiring layers. A TSV encapsulation contacts the sidewall of the dielectric liner, where the TSV encapsulation resides on the top surface of the semiconductor substrate. A moisture oxidation collar in an interlayer dielectric material around the TSV encapsulation. The interlayer dielectric material separates the moisture oxidation collar from the plurality of front side interconnect wiring layers surrounding the moisture oxidation collar.

Aspects of the disclosed invention relate to a method of forming a TSV encapsulant including forming front side interconnect wiring with known back-end-of-line semiconductor fabrication processes and etching a top portion of a through-silicon-via (TSV) via hole above a semiconductor substrate. The method includes depositing a layer of a refractory metal as a TSV encapsulant and then, removing horizontal portions of the layer of the refractory metal. The method includes depositing a layer of a dielectric liner material on the TSV encapsulant material and, then removing horizontal portions of the layer of the dielectric liner material. The method includes etching a bottom portion of the TSV via hole in the semiconductor substrate.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-sectional view of a semiconductor structure with an upper TSV encapsulation around a through-silicon-via (TSV), in accordance with an embodiment of the present invention.

FIG. 2 depicts a top view of the semiconductor structure of FIG. 1, in accordance with an embodiment of the present invention.

FIG. 3 depicts a cross-sectional view of a semiconductor structure after etching an opening for the upper TSV encapsulation and the TSV in the front side interconnect wiring, in accordance with an embodiment of the present invention.

FIG. 4 depicts a cross-sectional view of the semiconductor structure after depositing a metal material for the upper TSV encapsulation over the semiconductor structure; in accordance with an embodiment of the present invention.

FIG. 5 depicts a cross-sectional view of the semiconductor structure after performing an anisotropic etch of the metal material for the upper TSV encapsulation; in accordance with an embodiment of the present invention.

FIG. 6 depicts a cross-sectional view of the semiconductor structure after depositing a dielectric material over the semiconductor structure, in accordance with an embodiment of the present invention.

FIG. 7 depicts a cross-sectional view of the semiconductor structure after performing an anisotropic etch of the dielectric material; in accordance with an embodiment of the present invention.

FIG. 8 depicts a cross-sectional view of the semiconductor structure after etching a bottom portion of the TSV via hole in a semiconductor substrate, in accordance with an embodiment of the present invention.

FIG. 9 depicts a cross-sectional view of the semiconductor structure after depositing a layer of TSV insulation and a metal diffusion barrier, in accordance with an embodiment of the present invention.

FIG. 10 depicts a cross-sectional view of the semiconductor structure after depositing a metal fill for the TSV and performing a chemical-mechanical polish (CMP), in accordance with an embodiment of the present invention.

FIG. 11 depicts a cross-sectional view of a semiconductor structure without the dielectric liner removed from the top surface of the semiconductor structure of FIG. 5 after depositing a metal fill for the TSV and performing a chemical-mechanical polish (CMP), in accordance with an embodiment of the present invention.

FIG. 12 depicts a cross-sectional view of a semiconductor structure without a moisture oxidation collar after forming the TSV encapsulation with the dielectric liner in the top portion of the TSV via hole and etching a bottom portion of the TSV via hole, in accordance with an embodiment of the present invention.

FIG. 13 depicts a cross-sectional view of a semiconductor structure without a moisture oxidation collar after forming the TSV, in accordance with an embodiment of the present invention.

FIG. 14 depicts a top view of the semiconductor structure of FIG. 13, in accordance with an embodiment of the present invention.

FIG. 15 depicts a cross-sectional view of the semiconductor structure of FIG. 13 with the dielectric liner on the top surface of the front side interconnect wiring, a first portion of the ILD, and on the upper TSV encapsulation, in accordance with an embodiment of the present invention.

FIG. 16 depicts the process steps to form the semiconductor structure of FIG. 12, in accordance with an embodiment of the present invention.

### DETAILED DESCRIPTION

Embodiments of the present invention recognize that moisture penetration into one or more layers of the front side interconnect wiring during through-silicon-via formation reduces back-end-of-line (BEOL) semiconductor yields and creates reliability concerns for the integrity of the front side interconnect wiring. Methods and semiconductor structures that prevent moisture ingress into the front side interconnect wiring during TSV silicon etching and metal deposition processes are advantageous for front side interconnect wiring reliability.

Embodiments of the present invention provide a semiconductor structure that includes a TSV encapsulation around the top portion of a via last TSV via hole and ultimately, around the completed TSV. Embodiments of the present invention provide TSVs and TSV via holes that are formed using known TSV via last process. The TSV encapsulation includes a layer of a refractory metal or metal nitride deposited in the top portion of the TSV via hole that is above the semiconductor substrate surface and within a portion of the interlayer dielectric of the front side interconnect wiring. The metal layers of the front side interconnect wiring do not extend into the portion of the interlayer dielectric surrounding the TSV via hole and do not contact the TSV encapsulation. The TSV encapsulation is electrically isolated from the completed TSV by at least a dielectric liner deposited inside of the top portion of the TSV via hole and directly on the TSV encapsulation.

In embodiments of the present invention, the top portion of the TSV via hole is etched inside a portion of the ILD of the front side interconnect wiring in the location of the completed TSV. The top portion of the TSV via hole is etched before etching the bottom portion of the TSV via hole in the semiconductor substrate and before the completion of the TSV. The method to form the TSV encapsulation includes the deposition of a layer of a refractory or metal nitride on the sidewall of the top portion of the TSV via hole. A dielectric material such as an oxide material, a nitride material, or combination of these is deposited on the refractory metal material of the TSV encapsulation in the top portion of the TSV via hole. The TSV encapsulation extends from the top surface of the front side interconnect wiring to the top surface of the semiconductor substrate. The TSV encapsulation provides a moisture barrier preventing moisture ingress into the front side interconnect wiring during the remaining semiconductor fabrication processes to form the TSV. In various embodiments, the TSV encapsulation around the top portion of the TSV via hole adjacent to the front side interconnect wiring protects the front side interconnect wiring adjacent to the top portion of the TSV via hole from moisture or chemicals during the semiconductor material etching process to form the bottom portion of the TSV via hole in the semiconductor substrate. The TSV encapsulation around the top portion of the TSV is electrically isolated from the TSV by the dielectric liner. In embodiments, the TSV encapsulation is grounded.

Embodiments of the present include the formation of a cylindrical capacitor around the top portion of the TSV. The cylindrical capacitor can be created using the TSV encapsulation and the dielectric liner. In embodiments of the present invention, the TSV includes a TSV insulation, a metal diffusion barrier, and the TSV fill metal, typically copper. In some embodiments, the TSV includes more or less of layers of materials lining the TSV via hole (e.g., one, none, or more of these TSV via hole liner layers including, but not limited to, the TSV insulation and other TSV via hole liner layers including the metal diffusion barrier). Additionally, embodiments of the present invention include a semiconductor structure with a grounded TSV encapsulation. The TSV encapsulation is electrically isolated from the front side interconnect wiring by a portion of the interlayer dielectric material of the front side interconnect wiring.

Embodiments of the present invention provide a semiconductor structure with a moisture oxidation collar formed, using known BEOL semiconductor fabrication processes, outside of the TSV encapsulation and around the location of the future completed TSV. The moisture oxidation collar is inside of the portion of the ILD of the front side interconnect wiring layers with metal wiring layers around the location of the future TSV. Providing both a moisture oxidation collar composed of stacked portions of the copper metal of each of the front side interconnect wiring layers and the TSV encapsulation provides extra protection against moisture penetration into one or more layers of the front side interconnect wiring during TSV formation processes. The semiconductor structure with both a moisture oxidation collar and TSV encapsulation of the top portion of a TSV, formed using a via last TSV process, provides improved BEOL yields and a very reliable front side interconnect wiring in terms of reliability issues or front side interconnect wiring degradation due to moisture ingress during TSV formation.

The present invention includes various semiconductor structures with TSV encapsulation with a dielectric liner directly on the top portion of the TSV via hole. The present invention also includes semiconductor structures and various methods of forming the semiconductor structures with the TSV encapsulation and dielectric liner where the dielectric liner resides on the top surface of the semiconductor structure and inside the top portion of the TSV. The methods discussed in embodiments of the present invention include methods to form the TSV encapsulation and dielectric liner after forming the front side interconnect wiring.

The various methods include an embodiment where etching the top portion of a TSV via hole inside a portion interlayer dielectric in the front side interconnect wiring occurs before depositing a refractory metal as the TSV encapsulation. The TSV encapsulation deposits on the bottom surface and the sidewall of the top portion of the TSV via hole and on the top surface of the semiconductor structure (e.g., on front side interconnect wiring 10 with ILD 3). After depositing the TSV encapsulation, an anisotropic etching process removes horizontal portions of the refractory metal. Next, a deposition a dielectric liner on the sidewall and bottom surface of the TSV encapsulation and on exposed horizontal surfaces of the semiconductor structure occurs, followed by a removal of the horizontal portions of the dielectric liner. Using known TSV formation processes, the TSV fill process is completed (e.g., with semiconductor substrate TSV via hole etching and the deposition of an insulating layer and a metal barrier layer in both the top and bottom portion of the TSV via hole before TSV metal deposition to fill the TSV via hole).

Embodiments of the present invention include another method of forming the TSV that includes skipping the process to remove the horizontal portions of the dielectric liner on the front side interconnect wiring. Embodiments of the present invention further include the method of forming the moisture oxidation collar with the front side interconnect wiring, using known semiconductor fabrication processes, followed by etching the top portion of the TSV via hole, depositing the TSV encapsulation, removing horizontal portions of the TSV encapsulation, depositing the dielectric liner, and removing horizontal portions of the dielectric liner before forming the TSV using known TSV formation processes.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process (e.g., patterning a resist or an organic planarization layer) followed by one or more etching processes. Some examples of etching processes include but are not limited to the following processes, such as a dry etching process using a reactive ion etch (RIE) or ion beam etch (IBE), a wet chemical etch process, or a combination of these etching processes.

TSV fabrication processes, as known in the art, may be formed with one or more TSV via hole liner materials. The TSV liner materials may include, but are not limited to, one or more of a TSV insulation layer, a metal diffusion barrier, and a copper seed layer. The completed TSV includes any TSV via hole liner layers and a metal fill, typically copper.

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to the device element scale.

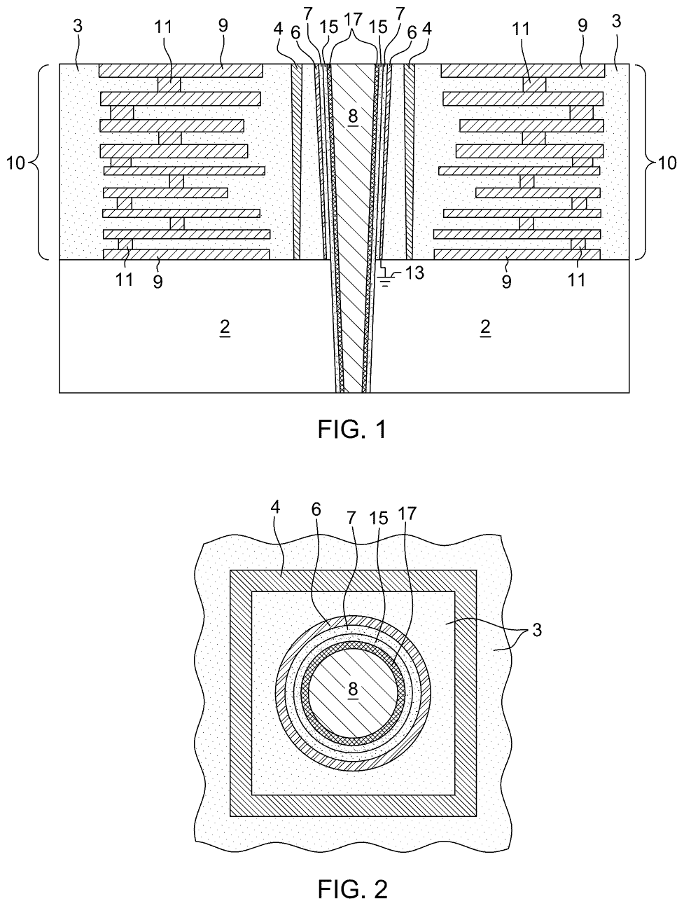

FIG. 1 depicts a cross-sectional view of a semiconductor structure with encapsulation 6 and dielectric liner 7 around an upper portion of through-silicon-via (TSV), in accordance with an embodiment of the present invention. As depicted, FIG. 1 includes semiconductor substrate 2, dielectric liner 7 around and inside encapsulation 6, the TSV with metal diffusion barrier 17, TSV insulation 15, and TSV metal fill 8, moisture oxidation collar 4 outside of ILD 3 and around TSV encapsulation 6, ground connection 13, front side interconnect wiring 10 formed in multiple layers of metal layers 9 connected by vias 11 in interlayer dielectric (ILD) 3. As depicted, FIG. 1 illustrates the semiconductor structure after the grinding process of the wafer backside to reveal the TSV bottom surface. It is understood that in addition to vias 11 and metal layers 9 in front side interconnect wiring 10, other features comprising middle of line or other device structures may also be contained in front side interconnect wiring 10 or may be placed on top of semiconductor substrate 2.

As depicted in FIG. 1, the bottom surface of TSV encapsulation 6 resides on the top surface of semiconductor substrate 2 and inside ILD 3 around moisture oxidation collar 4. The outer surface of TSV encapsulation 6 contacts a portion of ILD 3 and the inner surface of TSV encapsulation 6 contacts dielectric liner 7. As depicted in FIG. 1, TSV encapsulation 6 resides inside moisture oxidation collar 4 which is inside a portion of front side interconnect wiring 10. The top surface of TSV encapsulation 6 is level with the top surface of front side interconnect wiring 10 and extends down to contact the top surface of semiconductor substrate 2.

TSV encapsulation 6 can be composed of refractory metal or a metal nitride. As depicted later in FIG. 2, TSV encapsulation 6 has a substantially-circular cross-section. In various embodiments, TSV encapsulation 6 is a circular ring around dielectric liner 7 in the top portion of the TSV. The top portion of TSV can be above semiconductor substrate 2 and adjacent to front side interconnect wiring 10. In some embodiments, TSV encapsulation 6 is a rectangular tube or oval tube around dielectric liner 7 the top portion of the TSV in front side interconnect wiring 10 when the TSV has a rectangular or an oval-shaped horizontal cross-section. In this case, both moisture oxidation collar 4 and TSV encapsulation 6 have a rectangular shaped horizontal cross-section surrounding a top portion of the TSV.

In some embodiments, TSV encapsulation 6 is grounded. In various embodiments, TSV encapsulation 6 is attached by ground connection 13 to one or more ground lines, ground vias, or ground planes residing in semiconductor substrate 2. Using a known method of grounding a semiconductor element such as TSV encapsulation 6, ground connection 13 creates a connection of TSV encapsulation 6 with ground to provide a grounded TSV encapsulation 6 as depicted in FIG. 1. While not specifically depicted in FIG. 2 through FIG. 8, ground connection 13 can be present in the semiconductor structures of FIG. 2 through FIG. 8.

In various embodiments, TSV encapsulation 6 provides a moisture barrier to prevent moisture ingress into front side interconnect wiring 10. In other embodiments, TSV encapsulation 6 in combination with moisture oxidation collar 4 prevents moisture ingress into front side interconnect wiring 10 during the TSV formation. In particular, the combination of TSV encapsulation and moisture oxidation collar 4 protects front side interconnect wiring 10 from moisture and chemicals during semiconductor substrate 2 etching to create the bottom portion of the TSV via hole. As previously discussed, preventing moisture and/or chemical penetration into one or more layers of front side interconnect wiring 10 improves the semiconductor chip reliability and performance. Reducing the moisture penetration into BEOL fabricated interconnect wiring such as front side interconnect wiring 10, improves BEOL yields during TSV formation.

As depicted in FIG. 1, dielectric liner 7 is between TSV encapsulation 6 and TSV insulation 15. Dielectric liner 7 provides additional electrical isolation of TSV encapsulation 6 from the metal fill in the top portion of the TSV. In various embodiments, dielectric liner 7 directly contacts the TSV encapsulation 6 and TSV insulation 15 above semiconductor substrate 2.

In various embodiments, the combination of TSV encapsulation 6 and dielectric liner 7 create a cylindrical capacitor. The cylindrical capacitor composed of TSV encapsulation 6 and dielectric liner 7 surrounds the top portion of the TSV. In these embodiments, dielectric liner 7 can be an oxide material, a nitride material, or a high k dielectric material. Using a higher k dielectric material for dielectric liner 7 in the cylindrical capacitor can increase the capacitance of the cylindrical capacitor. As depicted, ILD 3 surrounds the outer portion of the sidewall of TSV encapsulation 6 and the inside and outside of the sidewall of moisture oxidation collar 4 to electrically isolate moisture oxidation collar 4 from TSV encapsulation 6 and the various layers of metal layers 9 and vias 11 in front side interconnect wiring 10.

As known to one skilled in the art, the TSV includes TSV insulation 15 deposited in both the top portion and the bottom portion of the TSV via hole and on the top surface of the semiconductor substrate. The deposition of TSV insulation 15, for example using ALD or CVD, lines the TSV via hole and covers the top surface of the semiconductor structure. In various embodiments, TSV insulation 15 covers the sidewall of dielectric liner 7 in the top portion of the TSV hole and the sidewall and exposed bottom surface of semiconductor substrate 2 in the bottom portion of the TSV via hole in semiconductor substrate 2. TSV insulation 15 can be composed of any known TSV insulation material such as, but not limited to dielectric nitrides (e.g., SiN or SiNₓ:H), oxides, or combinations thereof. As known in the art, a metal diffusion barrier layer such as metal diffusion barrier 17 is typically deposited on TSV insulation 15.

In various embodiments, metal diffusion barrier 17 is deposited on TSV insulation 15. Horizontal portions of metal diffusion barrier 17 can be removed as depicted in FIG. 1. Metal diffusion barrier 17 can typically be composed of a metal nitride such as TaN/Ta bilayer, TaN, Ta, TiN, or WN but is not limited to these metal diffusion barrier materials. TSV insulation 15 and metal diffusion barrier 17 can be deposited as a thin layer, typically in the range of 1 to 100 nm but are not limited to these thicknesses. A TSV metal fill 8, typically, copper, can be deposited to form the TSV. After the TSV is filled, a CMP process removes the horizontal portions of the metal diffusion barrier 17 and optionally some or all of the TSV insulation 15 from the top surface of the semiconductor structure. As previously discussed, in various embodiments, the TSV includes TSV insulation 15, metal diffusion barrier 17, and TSV metal fill 8. As depicted in FIG. 1, a wafer grinding and/or wafer etching process removes the bottom portion of semiconductor substrate 2 and exposes the bottom surface of the TSV.

ILD 3 can be composed of any known dielectric material or dielectric materials used in semiconductor chips for interlayer dielectric materials. ILD 3, depicted in FIG. 1, is composed of two or more layers of dielectric material electrically isolating the various metal layers 9, moisture oxidation collar 4, and TSV encapsulation 6. As known to one skilled in the art, ILD 3 can be composed of more than one dielectric material.

Semiconductor substrate 2 can be any semiconductor substrate material used in forming semiconductor chips including but limited to silicon, silicon germanium, germanium, or any other semiconductor material used in semiconductor device processing. In various embodiments, semiconductor substrate 2 includes a bottom portion of the TSV. Not depicted in FIG. 1 are the semiconductor devices formed directly on and in a top portion of semiconductor substrate 2. As known to one skilled in the art, the semiconductor devices are formed using known front-end-of-line (FEOL) semiconductor fabrication processes above and/or in a top portion of semiconductor substrate 2. Any type of semiconductor device or passive device can be formed on semiconductor substrate 2 in embodiments of the present invention. As known to one skilled in the art, one or more layers of the middle of line (MOL) metal layers (not depicted) may be present in FIG. 1 above the semiconductor devices. Semiconductor substrate 2 is depicted in FIG. 1 below at least front side interconnect wiring 10, moisture oxidation collar 4, dielectric liner 7, and TSV encapsulation 6.

Moisture oxidation collar 4 is a known semiconductor chip structure used in various semiconductor chip applications to prevent moisture ingress into the layers of front side interconnect wiring 10 during the TSV formation. In semiconductor structures without moisture oxidation collar 4 (not depicted in FIG. 1), moisture and/or chemical ingress into front side interconnect wiring 10 can occur after TSV via etching during subsequent TSV formation processes (e.g., during TSV etch in semiconductor substrate 2, various TSV liner depositions, and TSV fill). In semiconductor structures without moisture oxidation collar 4 and TSV encapsulation 6, moisture and/or chemicals may penetrate one or more layers of front side interconnect wiring 10 creating reliability and/or electrical performance issues with the completed semiconductor chip. While moisture oxidation collar 4 is depicted as a single layer or tube around TSV encapsulation 6, in other cases, moisture oxidation collar 4 may be composed of two rings or tubes around TSV encapsulation 6 and the TSV.

As known to one skilled in the art, moisture oxidation collar 4 can be formed around the planned location of TSV surrounding the area where the TSV via hole will be etched. Using known semiconductor fabrication processes, moisture oxidation collar 4 is formed layer by layer in front side interconnect wiring 10 by stacking a portion of each of metal layer 9 around the location of the TSV via to be etched later. In typical semiconductor chip structures, moisture oxidation collar 4 is a square or rectangular-shaped column, composed of copper. Using known BEOL semiconductor fabrication processes, moisture oxidation collar 4 can be formed in the location of a future TSV by stacking a portion of each metal layer 9 in front side interconnect wiring 10 on each other. The area inside of moisture oxidation collar 4 after completing the BEOL semiconductor processes and immediately outside of moisture oxidation collar 4 is composed of ILD 3.

In various embodiments, moisture oxidation collar 4 both creates an area penalty in front side interconnect wiring 10 and provides reliability and performance advantages in the semiconductor structure of the completed semiconductor chip by protecting front side interconnect wiring 10 from moisture during TSV formation. The area penalty is the unused semiconductor area of front side interconnect wiring 10 that is electrically isolated by ILD 3 from the outside of moisture oxidation collar 4 and the semiconductor area inside of moisture oxidation collar 4 is also, composed of ILD 3, where the TSV via will be etched later. In some cases, the unused semiconductor area inside moisture oxidation collar 4 between moisture oxidation collar 4 and TSV encapsulation 6 and the unused semiconductor area between moisture oxidation collar 4 and front side interconnect wiring 10 can be known as the keep out zone.

As depicted in FIG. 1, front side interconnect wiring 10 is formed above semiconductor substrate 2 and the semiconductor devices (not depicted). As known to one skilled in the art, front side interconnect wiring 10 is formed using known backend-of-line (BEOL) semiconductor fabrication processes and can be composed of numerous metal layers 9 that are vertically connected by one or more of vias 11. Metal layers 9 can be electrically isolated by one or more layers of ILD 3. While FIG. 1 depicts nine horizontal metal layers 9 each connected by at least one of vias 11, in other examples, any number of metal layers 9 and vias 11 can be present in other examples. As known to one skilled in the art, in various embodiments, front side interconnect wiring 10 formed with metal layers 9, vias 11, and ILD 3 are present adjacent to moisture oxidation collar 4. As depicted in FIG. 1, ILD 3 contacts all sidewalls of moisture oxidation collar 4.

FIG. 2 depicts a top view of a center portion of the semiconductor structure of FIG. 1, in accordance with an embodiment of the present invention. As depicted, FIG. 2 includes moisture oxidation collar 4 surrounded by a portion of ILD 3. Moisture oxidation collar 4, in the top view, has a square shape around TSV encapsulation 6. Viewed from the top, TSV encapsulation 6 is circular and is electrically isolated from moisture oxidation collar 4 by another portion of ILD 3.

Dielectric liner 7, in the top view, is a circular tube sandwiched between TSV encapsulation 6 and TSV insulation 15. As previously discussed, metal diffusion barrier 17 is around TSV insulation 15. Metal diffusion barrier 17 is between TSV insulation 15 and TSV metal fill 8.

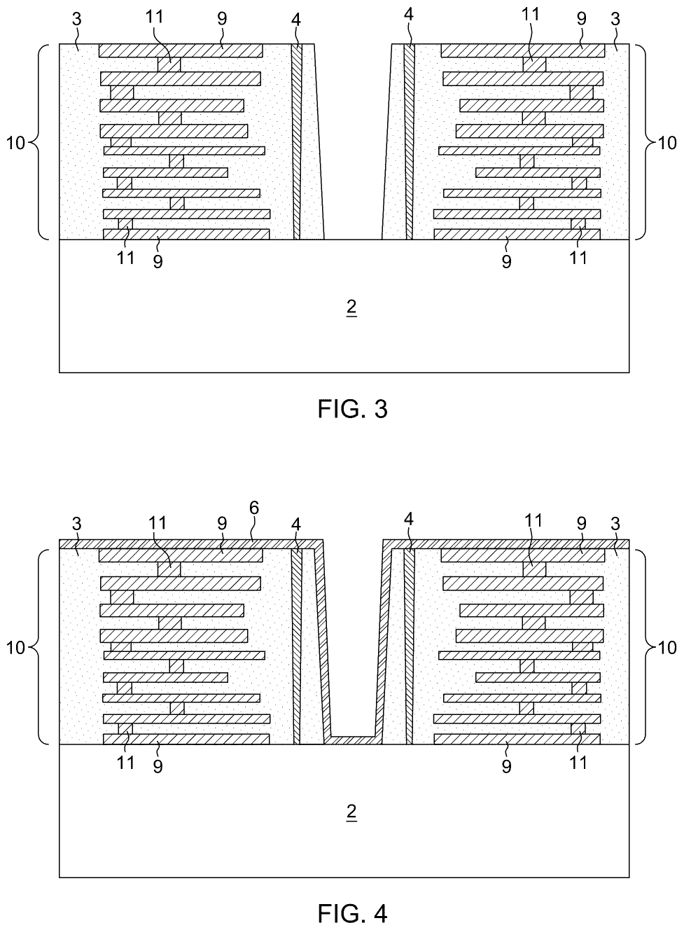

FIG. 3 depicts a cross-sectional view of a semiconductor structure of FIG. 1 after etching an opening in ILD 3, in accordance with an embodiment of the present invention. As depicted, FIG. 3 includes front side interconnect wiring 10 with metal layers 9 and vias 11 that are separated by ILD 3 from moisture oxidation collar 4 on semiconductor substrate 2. A top portion of a TSV via hole in ILD 3 is formed on semiconductor substrate 2 in the center of moisture oxidation collar 4.

Using a known patterning (e.g., organic planarization layer or resist patterning) and an etching process (e.g., RIE), an opening or via hole can be etched inside moisture oxidation collar 4. The etching process stops on semiconductor substrate 2. As depicted in FIG. 3, ILD 3 forms the sidewalls of the top portion of the TSV via hole. Semiconductor substrate 2 is the bottom surface of the top portion of the TSV via hole. As depicted, the top portion of the TSV is etched above semiconductor substrate 2 inside moisture oxidation collar 4. The via hole for the top portion of the TSV is inside and outside of ILD 3 adjacent to portions of front side interconnect wiring 10. The thickness of ILD 3 remaining inside of moisture oxidation collar 4 will be sufficient to prevent shorting between any metal layer deposited for TSV encapsulation 6 (e.g., greater than four nm thickness of the remaining sidewall of ILD 3 inside of moisture oxidation collar 4).

FIG. 4 depicts a cross-sectional view of the semiconductor structure after depositing a metal material for TSV encapsulation 6 over the semiconductor structure, in accordance with an embodiment of the present invention. As depicted, FIG. 4 includes the elements of FIG. 3 with a layer of metal material for TSV encapsulation 6.

Using a known deposition process, a layer of a metal material for TSV encapsulation 6. The metal material deposited for TSV encapsulation 6 can be a refractory metal or a metal nitride such as but not limited to TaN, TiN, Ta, Ti, W, Mo, or WN. The layer of metal material for TSV encapsulation 6 can be deposited over the exposed surfaces of the semiconductor structure. For example, a two to fifty nanometer thick layer of the refractory metal or metal nitride is deposited on exposed surfaces of front side interconnect wiring 10, moisture oxidation collar 4, ILD 3, and semiconductor substrate 2. In a preferred deposition method, PVD deposits the layer of refractory metal or metal nitride for TSV encapsulation 6 where the PVD deposition can enhance the thickness of the sidewall deposition of TSV encapsulation 6 metal material while minimizing the thickness of the metal material for TSV encapsulation 6 on horizontal surfaces such as in the bottom of the via hole and on the top surfaces of front side interconnect wiring 10, ILD 3, and moisture oxidation collar 4. The layer of the metal material (e.g., TiN, TaN, Ta) will act as a moisture barrier during later TSV formation processes. The combination of TSV encapsulation 6 and moisture oxidation collar 4 both provide a moisture barrier protecting font side interconnect wiring 10 during subsequent TSV formation processes.

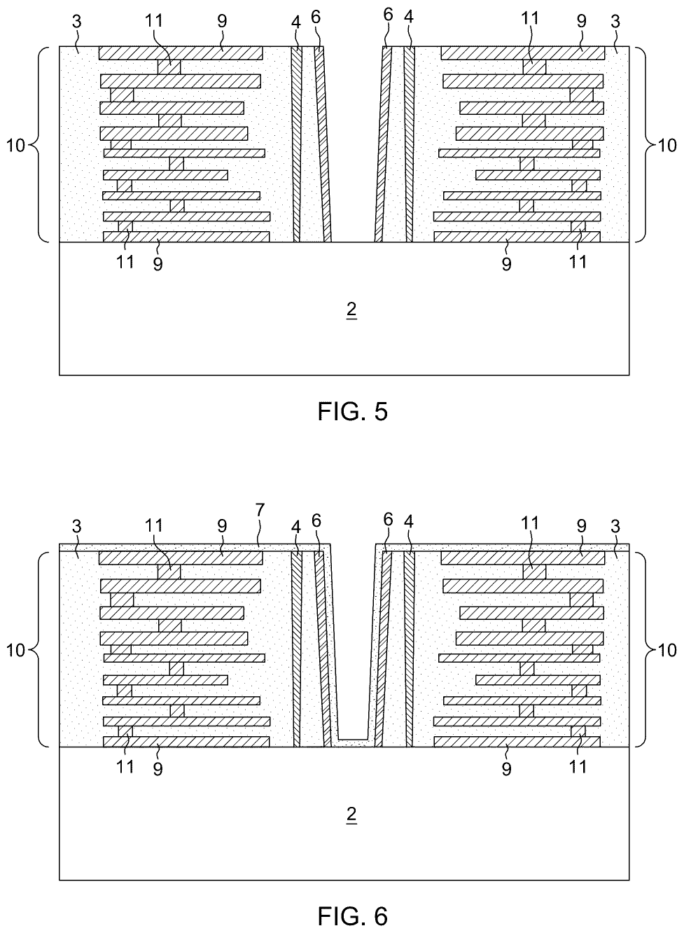

FIG. 5 depicts a cross-sectional view of the semiconductor structure after performing an anisotropic etch of the metal material for TSV encapsulation 6, in accordance with an embodiment of the present invention. Using a known anisotropic etching process (e.g., Ar sputter etching process), the exposed horizontal portions of the refractory metal or metal nitride layer of TSV encapsulation 6 can be removed. After the etching process, TSV encapsulation 6 remains on the sidewall of ILD 3 inside of moisture oxidation collar 4 as depicted in FIG. 5.

FIG. 6 depicts a cross-sectional view of the semiconductor structure after depositing a dielectric material over the semiconductor structure for dielectric liner 7, in accordance with an embodiment of the present invention. As depicted, FIG. 6 includes the elements of FIG. 5 with dielectric liner 7 over the top surfaces of front side interconnect wiring 10, moisture oxidation collar 4, semiconductor substrate 2, and the sidewall and top surface of TSV encapsulation 6.

Using a known deposition process such as CVD, PVD, or ALD, a layer of a dielectric material such as but not limited to an oxide (e.g., SiO₂), a nitride, or a combination of these materials can be deposited on the exposed surfaces of the semiconductor structure. For example, dielectric liner 7 may have a thickness ranging from ten to one hundred nm but is not limited to these thicknesses.

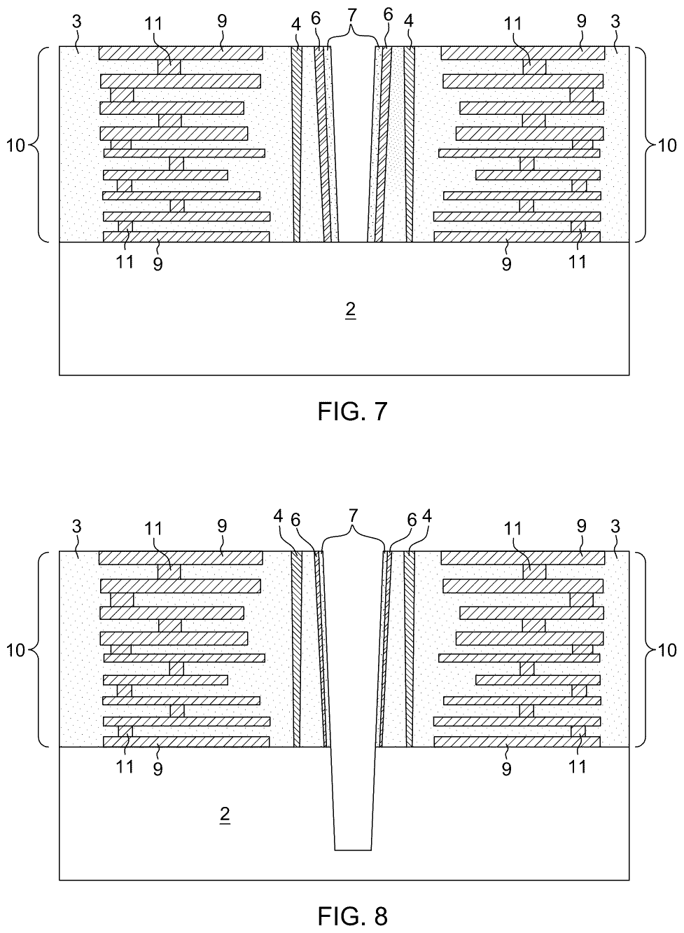

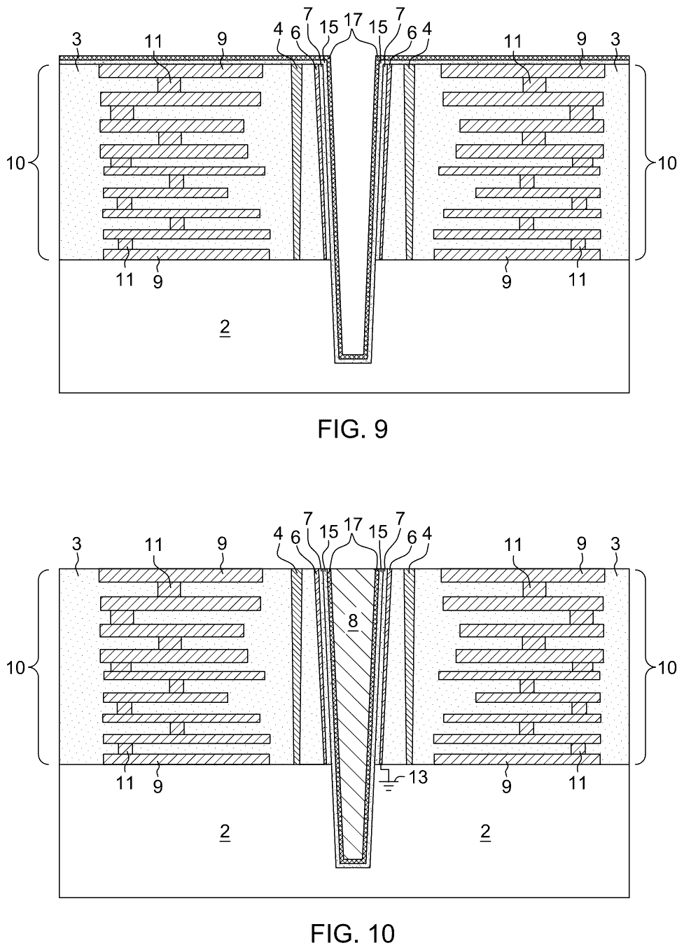

In some embodiments, the semiconductor structure of FIG. 6 is used to form the semiconductor structure of FIG. 10. In these embodiments, the horizontal surfaces of dielectric liner 7 are not removed as depicted and discussed later with respect to FIG. 7. In these embodiments, the step removing the horizontal portions of dielectric liner 7 is not performed. In other words, the step of removing horizontal portions of dielectric liner 7 depicted in FIG. 7 is an optional process. In these embodiments, dielectric liner 7 remains on both the horizontal surfaces and vertical surfaces of the semiconductor structure of FIG. 8. In these embodiments, after performing the steps depicted in FIGS. 8-9, results in the semiconductor structure of FIG. 10 with TSV metal fill 8, TSV insulation 15, metal diffusion barrier 17, TSV encapsulation 6, and dielectric liner 7 where dielectric liner 7 remains on the top surface of front side interconnect wiring 10, ILD 3, moisture oxidation collar 4, and TSV encapsulation 6.

FIG. 7 depicts a cross-sectional view of the semiconductor structure after the optional step of removing horizontal portions of dielectric liner 7, in accordance with an embodiment of the present invention. As depicted, FIG. 7 includes the elements of FIG. 6 without the horizontal portions of dielectric liner 7.

Using one of an anisotropic etching process (e.g., RIE) or an optional OPL patterning and etching process, the exposed horizontal portions of dielectric liner 7 are removed. After the etching process, dielectric liner 7 remains on the sidewall of TSV encapsulation 6 inside the via hole for the TSV.

FIG. 8 depicts a cross-sectional view of the semiconductor structure after etching a bottom portion of the TSV via hole in semiconductor substrate 2, in accordance with an embodiment of the present invention. In various embodiments, using one or more known semiconductor substrate etching processes (e.g., a dry or wet silicon etching process), the top portion of the TSV via hole about semiconductor substrate 2 is extended down through at least the top and middle portions of semiconductor substrate 2 as depicted in FIG. 8. The TSV via hole now extends from the top surface of TSV encapsulation 6 and dielectric liner 7 in ILD 3 down into a bottom or lower portion of semiconductor substrate 2 as depicted in FIG. 8. The TSV via hole extends through TSV encapsulation 6 and dielectric liner 7 adjacent to front side interconnect wiring 10 and partially through semiconductor substrate 2. TSV encapsulation 6 and moisture oxidation collar 4 prevent the ingress of moisture and/or semiconductor etching chemicals into front side interconnect wiring 10 during the semiconductor substrate etching process to form the bottom portion of the TSV via hole in semiconductor substrate 2.

In some embodiments, the horizontal portions of dielectric liner 7 deposited in FIG. 6 are not removed by the optional step depicted in FIG. 7 of removing the horizontal portions of dielectric liner 7. When the horizontal portion of dielectric liner 7 remains on a portion of semiconductor substrate 2 as depicted in FIG. 6, after patterning (e.g., OPL deposition and patterning) and using one or more known dielectric etching processes, the horizontal portion of dielectric liner 7 on semiconductor substrate 2 can be removed. A second etching process, using known TSV via hole etching processes (e.g., RIE), removes the exposed portion of semiconductor substrate 2 between the vertical sidewall of dielectric liner 7 on TSV encapsulation 6 to a depth that can almost extend to the bottom surface of semiconductor substrate 2. In these embodiments, dielectric liner 7 remains on the top surface of front side interconnect wiring 10, moisture oxidation collar 4, ILD 3, and TSV encapsulation 6 as depicted later in FIG. 10.

FIG. 9 depicts a cross-sectional view of the semiconductor structure after using known TSV formation processes to deposit TSV insulation 15 in the TSV via hole, then, to deposit metal diffusion barrier 17 on TSV insulation 15, in accordance with an embodiment of the present invention. As depicted, FIG. 9 includes the elements of FIG. 8 with TSV insulation 15 and metal diffusion barrier 17 on the exposed surfaces of the semiconductor structure.

Using known TSV liner material deposition processes (e.g., ALD, CVD, PECVD), TSV insulation 15 deposits on the top surface of front side interconnect wiring 10, ILD 3, the sidewall and bottom surface of the top portion of the TSV via hole. TSV insulation 15 can be deposited directly on dielectric liner 7 in the top portion of the TSV via hole and on the exposed sidewall of semiconductor substrate 2 in the bottom portion of the TSV via hole. As depicted, metal barrier diffusion metal 17 is deposited on TSV insulation 15.

FIG. 10 depicts a cross-sectional view of the semiconductor structure after depositing TSV metal fill 8, in accordance with an embodiment of the present invention. As depicted, FIG. 10 includes the elements of FIG. 9 without TSV insulation 15 and metal diffusion barrier 17 on the top surface of front side interconnect wiring 10 and with TSV metal fill 8. As known to one skilled in the art, the TSV can be filled with a TSV fill metal 8 and includes TSV insulation 15 and metal diffusion barrier 17.

Deposited with known TSV formation processes, TSV fill metal 8 such as but not limited to copper can be deposited on the exposed top surfaces of the semiconductor structure of FIG. 10 filling the TSV via hole. A CMP can remove excess TSV insulation 15, metal diffusion barrier 17, and the excess TSV fill metal 8 from the top surface of the semiconductor structure.

As depicted in FIG. 10, the top portion of the TSV is above the top surface of semiconductor substrate 2. The top portion of the TSV is surrounded by dielectric liner 7 and TSV encapsulation 6. As depicted in FIG. 10, TSV insulation 15 resides directly on dielectric liner 7 in the top portion of the TSV. The bottom portion of the TSV with metal diffusion barrier 17 and TSV insulation 15 resides in semiconductor substrate 2 as depicted in FIG. 10.

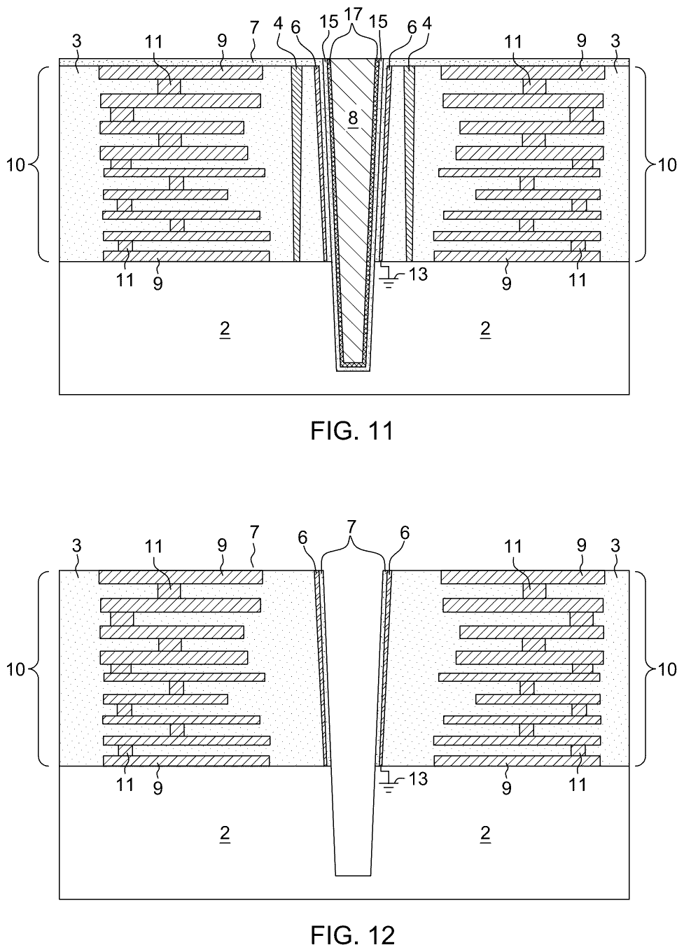

FIG. 11 depicts a cross-sectional view of a semiconductor structure without dielectric liner 7 removed from the top surface of the semiconductor structure of FIG. 5 after depositing a metal fill for the TSV and performing a chemical-mechanical polish (CMP), in accordance with an embodiment of the present invention. As depicted, FIG. 11 includes the elements of FIG. 10 with the addition of dielectric liner 7 on the top surface of front side interconnect wiring 10, moisture oxidation collar 4, and TSV encapsulation 6.

To form the semiconductor structure of FIG. 11, the optional step of removing the horizontal portions of dielectric liner 7 depicted in FIG. 7 is not performed. As previously discussed with respect to FIG. 7, in this embodiment, before etching the bottom portion of the TSV via hole in semiconductor substrate 2, a selective etching process can remove the remaining horizontal portion of dielectric liner 7 on semiconductor substrate 2 followed by the etching of the bottom portion of the TSV via hole in semiconductor substrate 2 using known TSV etching processes.

As discussed previously with respect to the semiconductor structure of FIG. 1, the semiconductor structure of FIG. 11 can include a grounded TSV encapsulation 6 using ground connection 13. In other embodiments, the combination of TSV encapsulation 6 and dielectric liner 7 form a cylindrical capacitor around the top portion of the TSV. In this case, the dielectric material of dielectric liner 7 can be a high k dielectric material to improve the capacitance of the cylindrical capacitor around the TSV. Similar to the semiconductor structure of FIG. 1, the semiconductor structure of FIG. 11 reduces moisture ingress into front side interconnect wiring 10 improving both the reliability of the semiconductor chip and the BEOL yields during semiconductor chip fabrication.

FIG. 12 depicts a cross-sectional view of a semiconductor structure without a moisture oxidation collar 4 and with the bottom portion of the TSV via hole extending into the semiconductor substrate, in accordance with an embodiment of the present invention. As depicted, FIG. 12 includes the elements of FIG. 8 without moisture oxidation collar 4. As depicted in FIG. 12, moisture oxidation collar 4 is not formed during BEOL semiconductor fabrication processes. Without moisture oxidation collar 4, the area of the two portions ILD 3 without metal wiring layers 9 around moisture oxidation collar 4 and TSV encapsulation 6 in FIG. 8 can be reduced in FIG. 12. As depicted in FIG. 12, only one portion of ILD 3 with metal layers 9 is present adjacent to TSV encapsulation 6. In this way, more front side interconnect wiring 10 can be utilized while still providing moisture protection for front side interconnect wiring 10 using TSV encapsulation 6.

Similar to FIG. 8, using known TSV semiconductor substrate via etching processes, the TSV via hole can be extended down into a portion of semiconductor substrate 2. As previously discussed, TSV encapsulation 6 with dielectric liner 7 surrounds the top portion of the TSV via hole and can be electrically isolated by ILD 3 without metal layers 9 from front side interconnect wiring 10. TSV encapsulation 6 provides a moisture barrier between the top portion of the TSV via hole and front side interconnect wiring 10.

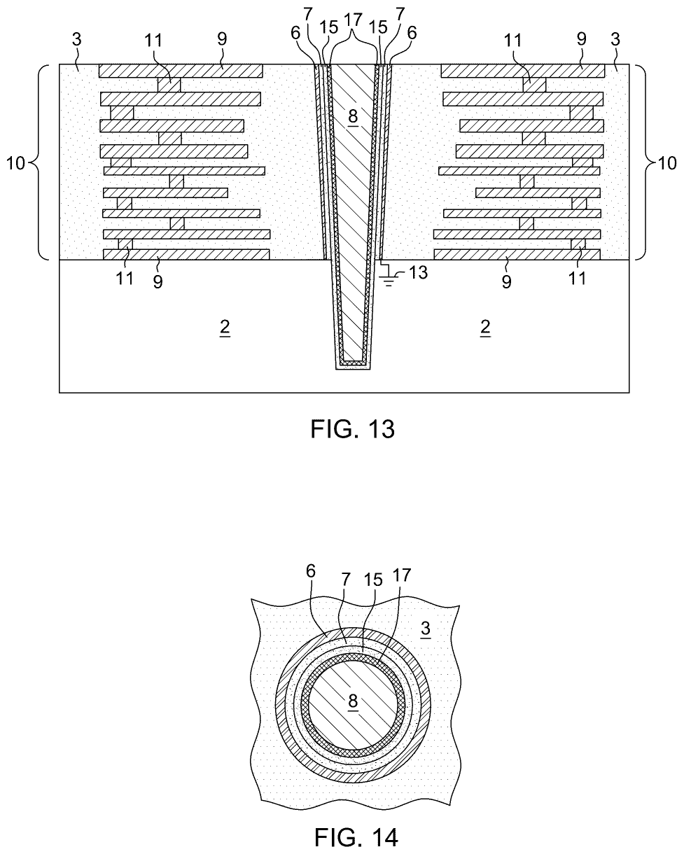

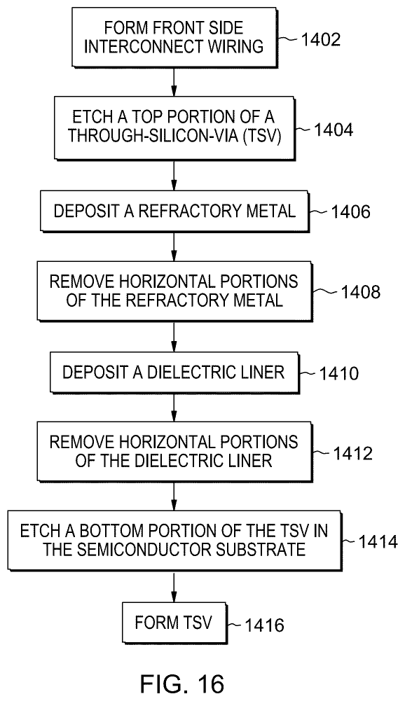

FIG. 13 depicts a cross-sectional view of a semiconductor structure without moisture oxidation collar 4 and with TSV metal fill 8, in accordance with an embodiment of the present invention. As depicted, FIG. 13 includes the elements of FIG. 12 with TSV insulation 15, metal diffusion barrier 17, and TSV metal fill 8. As known to one skilled in the art, the semiconductor structure of FIG. 13 can be formed using the process steps previously discussed in detail with respect to FIGS. 3 through 11. One example of the process steps to form the semiconductor structure of FIG. 13 is briefly summarized in FIG. 16.

Removing the moisture oxidation collar as depicted in FIG. 13 reduces the unused semiconductor interconnect wiring area around the top portion of the TSV. As depicted in FIG. 13, only a portion of ILD 3 adjacent to upper TSV encapsulation 6 is needed to electrically isolate the outside surface of the sidewall of TSV encapsulation 6. As depicted in FIG. 13, the portion of ILD 3 needed to electrically isolate moisture oxidation collar 4 from front side interconnect wiring 10 in the semiconductor structure of FIG. 1 is eliminated along with the moisture oxidation collar 4. The semiconductor area, depicted in FIG. 1, required to electrically isolate moisture oxidation collar 4 can now be used for semiconductor device wiring (e.g., as more of front side interconnect wiring 10 is available for semiconductor interconnect wiring). Removing the moisture oxidation collar provides more semiconductor real estate for wiring during BEOL semiconductor fabrication. Providing additional semiconductor real estate, in some cases, can reduce the space between adjacent semiconductor devices and/or improve semiconductor device and/or semiconductor chip electrical performance. In FIG. 13, TSV encapsulation 6 provides a moisture barrier to prevent moisture from the TSV formation processes from entering portions of front side interconnect wiring 10. In this way, TSV encapsulation 6 with dielectric liner 7 improves the semiconductor chip reliability and can improve BEOL fabrication process yields while also, providing additional area for front side interconnect wiring 10 compared to the semiconductor structure of FIG. 1.

The semiconductor structure of FIG. 13 can provide a grounded TSV encapsulation 6 similar to FIG. 1. In various embodiments, the semiconductor structure of FIG. 13 includes ground connection 13. The combination of TSV encapsulation 6 and dielectric liner 7 can form a cylindrical capacitor around the top portion of the TSV. In these embodiments where a capacitor is formed around the top portion of the TSV using dielectric liner 7 and TSV encapsulation 6, where dielectric liner 7 is composed of a high k dielectric material. In some embodiments, the TSV and TSV encapsulation 6 have a rectangular or oval-shaped horizontal cross-section.

FIG. 14 depicts a top view of the semiconductor structure of FIG. 13, in accordance with an embodiment of the present invention. As depicted, FIG. 14 includes the elements of FIG. 2 without moisture oxidation collar 4.

The top view of TSV encapsulation 6 inside of dielectric liner 7 is circular or a ring directly inside ILD 3. TSV insulation 15 is inside and contacts dielectric liner 7. Metal diffusion barrier 17 is inside and directly contacts TSV metal fill 8. In various embodiments, TSV encapsulation 6 forms a tube around the top portion of the TSV.

In other embodiments, the TSV and TSV encapsulation 6 can have a rectangular or oval-shaped horizontal cross-section. As depicted in FIG. 14, a portion of ILD 3 is outside of TSV encapsulation 6. In FIG. 14, ILD 3 between the square moisture oxidation collar 4 and TSV encapsulation 6 is not depicted. By removing moisture oxidation collar 4 and ILD 3 between square moisture oxidation collar 4 and TSV encapsulation 6 depicted in the semiconductor structure of the top view of FIG. 2, the area of removed moisture oxidation collar 4 and the dielectric material of ILD 3 required to electrically isolate moisture oxidation collar 4 from TSV encapsulation 6 can be utilized for additional semiconductor wiring in FIG. 14 and FIG. 13. Front side interconnect wiring 10 (not depicted in FIG. 14) is outside of ILD 3 around TSV encapsulation 6 as depicted in FIG. 13.

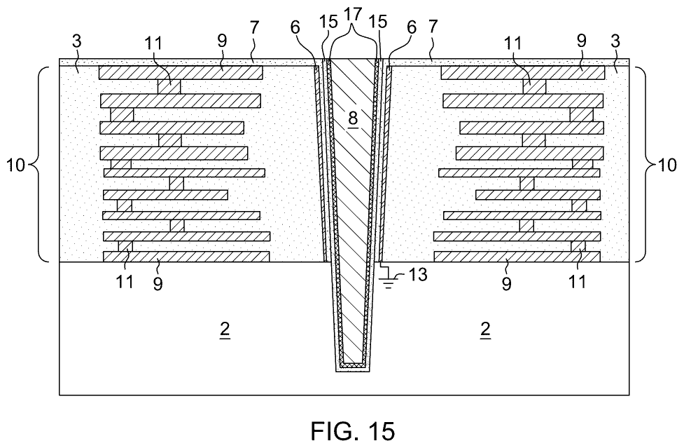

FIG. 15 depicts a cross-sectional view of the semiconductor structure of FIG. 13 with dielectric liner 7 on the top surface of front side interconnect wiring 10, portions of ILD 3, and on TSV encapsulation 6, in accordance with an embodiment of the present invention.

The semiconductor structure of FIG. 15 without moisture oxidation collar 4 and with the horizontal portions of dielectric liner 7 remaining on front side interconnect wiring 10, a first portion of ILD 3, and on TSV encapsulation 6. Without forming the moisture oxidation collar during the BEOL fabrication process and using the process steps as discussed previously with respect to FIGS. 3-11, the semiconductor structure of FIG. 15 can be formed.

The semiconductor structure of FIG. 15 is similar to the semiconductor structure of FIG. 13 with the addition of dielectric liner 7 on the top surface of the semiconductor structure except for the top surface of the TSV.

The semiconductor structure of FIG. 15 has similar or the same attributes as the semiconductor structure of FIG. 13 (e.g., TSV encapsulation 6 can be grounded, TSV encapsulation 6 can be a capacitor with dielectric liner 7, TSV encapsulation 6 can be a moisture barrier, and the semiconductor structure of FIG. 15 can provide more semiconductor chip wiring in front side interconnect wiring 10 than the semiconductor structure of FIG. 1).

FIG. 16 depicts the process steps to form the semiconductor structure of FIG. 10, in accordance with an embodiment of the present invention.

In step 1402, using BEOL fabrication processes form front side interconnect wiring with a moisture oxidation collar. In other embodiments, the BEOL fabrication processes form front side interconnect wiring without a moisture oxidation collar. In step 1404, using known TSV via etching processes, etch a top portion of a TSV via hole where the top portion of the TSV via hole terminates on the top surface of the semiconductor substrate. In step 1406, using a deposition process such as PVD, deposit a layer of a refractory metal or a metal nitride on the exposed surfaces of the semiconductor structure. In step 1408, using an anisotropic etching process such as an argon sputtering process removes the exposed horizontal portions of the refractory metal. In step 1410, deposit a dielectric liner and then, in step 1412, using an anisotropic etching process, remove the horizontal portions of dielectric liner 7. In step 1414, using known TSV etching processes, etch the bottom portion of the TSV via hole in a portion of the semiconductor substrate.

In step 1416, after etching the bottom portion of the TSV via hole, using known TSV materials and processes, form the TSV. As known to one skilled in the art, the TSV via hole can be lined with a TSV insulating liner, typically an oxide, nitride, or bilayer of the two, and then a TaN/Ta bilayer as a metal diffusion barrier can be deposited on the TSV insulation. The TSV via can be filled with a conductive fill metal such as PVD deposited copper. A CMP can planarize the top surface of the semiconductor substructure. Using known semiconductor fabrication processes, a backside wafer grind can remove the bottom portion of the semiconductor substrate. The top portion of the TSV above the semiconductor substrate is inside the TSV encapsulation composed of the refractory metal. The TSV encapsulation is electrically isolated from the top portion of the TSV by at least the dielectric liner between the TSV and the TSV encapsulation.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a top portion of a through-silicon-via hole on a semiconductor substrate;
a dielectric liner surrounding a sidewall of the top portion of the through-silicon-via hole; and
a through-silicon-via encapsulation surrounding the dielectric liner.

2. The semiconductor structure of claim 1, further comprising:
an interlayer dielectric material contacting an outside surface of a sidewall of the through-silicon-via encapsulation;
a plurality of front side interconnect wiring layers electrically isolated from the through-silicon-via encapsulation by the interlayer dielectric material; and
a bottom portion of the through-silicon-via hole in the semiconductor substrate.

3. The semiconductor structure of claim 1, wherein:
the through-silicon-via encapsulation is composed of a metal nitride material; and the
dielectric liner is composed of an oxide dielectric material.

4. The semiconductor structure of claim 2, wherein the through-silicon-via encapsulation reduces moisture ingress into one or more of the plurality of front side interconnect wiring layers.

5. The semiconductor structure of claim 2, wherein:
a bottom surface of each of the through-silicon-via encapsulation and the dielectric liner each reside on a top surface of the semiconductor substrate; and
a top surface of each of the through-silicon-via encapsulation and the dielectric liner are level with a top surface of the plurality of front side interconnect wiring layers.

6. The semiconductor structure of claim 1, wherein the through-silicon-via encapsulation and the dielectric liner each have a circular horizontal cross-section.

7. The semiconductor structure of claim 1, wherein the through-silicon-via encapsulation and the dielectric liner are a cylindrical capacitor around the top portion of the through-silicon-via hole.

8. The semiconductor structure of claim 7, wherein the dielectric liner is composed of a high k dielectric material.

9. The semiconductor structure of claim 1, wherein the through-silicon-via encapsulation is grounded.

10. A semiconductor structure comprising:
a top portion of a through-silicon-via (TSV) above a top surface of a semiconductor substrate;
a dielectric liner surrounding a sidewall of the top portion of the TSV, wherein the dielectric liner resides on the top surface of the semiconductor substrate; and
a TSV encapsulation surrounding a sidewall of the dielectric liner, wherein the TSV encapsulation resides on the top surface of the semiconductor substrate.

11. The semiconductor structure of claim 10, further comprising:
a bottom portion of the TSV in the semiconductor substrate; and
a first interlayer dielectric material surrounding an outside surface of a sidewall of the TSV encapsulation and a sidewall of the semiconductor substrate in the bottom portion of the TSV.

12. The semiconductor structure of claim 10, further comprising:
a moisture oxidation collar on the top surface of the semiconductor substrate, wherein:
the moisture oxidation collar resides outside of the first interlayer dielectric material around the TSV encapsulation; and
a second interlayer dielectric material separates the moisture oxidation collar from a plurality of front side interconnect wiring layers surrounding the second interlayer dielectric material.

13. The semiconductor structure of claim 12, wherein the moisture oxidation collar has a rectangular horizontal cross-section and the TSV encapsulation has a circular horizontal cross-section.

14. The semiconductor structure of claim 11, wherein the TSV encapsulation and the dielectric liner are a circular capacitor around the top portion of the TSV.

15. The semiconductor structure of claim 11, wherein the TSV encapsulation is grounded.

16. The semiconductor structure of claim 11, wherein the dielectric liner contacts a top surface of the TSV encapsulation, the interlayer dielectric material, and a moisture oxidation collar.

17. A method comprising:
forming front side interconnect wiring with back-end-of-line semiconductor fabrication processes;
etching a top portion of a through-silicon-via (TSV) via hole above a semiconductor substrate;
depositing a layer of a metal nitride as a TSV encapsulant;
removing horizontal portions of the layer of the metal nitride;
depositing a layer of a dielectric liner material on the TSV encapsulant;
removing horizontal portions of the layer of the dielectric liner material; and
etching a bottom portion of the TSV via hole in the semiconductor substrate.

18. The method of claim 17, further comprising:
depositing a TSV insulating material in the top portion of the TSV via hole and the bottom portion of the TSV via hole;
depositing a metal diffusion barrier on the TSV insulating material;
filling the TSV via hole with copper to form the TSV; and
performing a chemical-mechanical polish.

19. The method of claim 18, wherein the layer of the dielectric liner electrically isolates the metal nitride from a top portion of the TSV.

20. The method of claim 18, wherein the TSV encapsulation is grounded.
